(19) United States
(12) Patent Application Publication
(10) Pub. No.: US 2025/0385643 A1
(43) Pub. Date: Dec. 18, 2025

(54) THREE STAGE POWER AMPLIFIER WITH PEAK OUTPUT MATCH

(71) Applicant: AXIRO SEMICONDUCTOR INC., San Diego, CA (US)

(72) Inventors: Ramzi DARRAJI, Ottawa, Ontario (CA); Shishir Ramasare Shukla, San Diego, CA (US); Ramanujam SRINIDHI EMBAR, San Diego, CA (US)

(73) Assignee: AXIRO SEMICONDUCTOR INC., San Diego, CA (US)

(21) Appl. No.: 18/742,112

(22) Filed: Jun. 13, 2024

(51) Int. Cl. H03F 1/02; H03F 1/56; H03F 3/24

(52) U.S. Cl. CPC H03F 1/0288; H03F 1/56; H03F 3/245; H03F 2200/192; H03F 2200/222; H03F 2200/225; H03F 2200/387

(57) ABSTRACT

Systems and circuits implementing an amplifier module are described. An integrated circuit can include a pre-driver stage, a driver stage and a final stage. The pre-driver stage can amplify an input signal to generate a first amplified signal. The driver stage can amplify the first amplified signal to generate a second amplified signal. The final stage can amplify the second amplified signal to generate an output amplified signal. The final stage can include a peak amplifier, a main amplifier, a peak input matching network, a peak output matching network, a main input matching network and a main output matching network. The peak output network can include a first matching section and a second matching section. The first matching section and the second matching section can perform different impedance matching. The main input matching network can include a harmonic trapping that traps a second harmonic of the second amplified signal.

### BACKGROUND

The present disclosure relates in general to power amplification systems and devices. Particularly, a three stage amplifier with peak output matching is described.

Wireless communication systems may employ power amplifiers for increasing the power of radio frequency (RF) signals. In a wireless communication system, a power amplifier in a final amplification stage of a transmission channel may facilitate amplification of a signal to an antenna for radiation over the air. High gain, high linearity, stability, and a high level of power-added efficiency are characteristics of a desirable amplifier in such a wireless communication system. In general, a power amplifier may operate at maximum power efficiency when the power amplifier transmits close to saturated power. However, power efficiency may degrade as output power decreases. Therefore, a high efficiency power amplifier architecture may be desirable for current and next-generation wireless systems.

### SUMMARY

In one embodiment, an integrated circuit implementing an amplifier module is generally described. The integrated circuit can include a pre-drive stage, a driver stage and a final stage. The pre-driver stage can be configured to amplify an input signal to generate a first amplified signal. The driver stage can be configured to amplify the first amplified signal to generate a second amplified signal. The final stage can be configured to amplify the second amplified signal to generate an output amplified signal. The final stage can include a peak amplifier, a main amplifier, a peak input matching network, a peak output matching network, a main input matching network and a main output matching network. The peak output network can include a first matching section and a second matching section. The first matching section and the second matching section can perform different impedance matching. The main input matching network can include a harmonic trapping section configured to trap a second harmonic of the second amplified signal.

In one embodiment, a system implementing a data transmitter is generally described. The system can include a plurality of antennas and a plurality of transmission channels. A transmission channel can include an amplifier module comprising a pre-driver stage, a driver stage and a final stage. The pre-driver stage can be configured to amplify an input signal to generate a first amplified signal. The driver stage can be configured to amplify the first amplified signal to generate a second amplified signal. The final stage can be configured to amplify the second amplified signal to generate an output amplified signal. The final stage can include a peak amplifier, a main amplifier, a peak input matching network, a peak output matching network, a main input matching network and a main output matching network. The peak output network can include a first matching section and a second matching section. The first matching section and the second matching section can perform different impedance matching. The main input matching network can include a harmonic trapping section configured to trap a second harmonic of the second amplified signal.

In one embodiment, The system can include a plurality of antennas, a plurality of receiver channels and a plurality of transmission channels. The plurality of receiver channels can be configured to process signals being received by the plurality of antennas. A transmission channel can include an amplifier module comprising a pre-driver stage, a driver stage and a final stage. The pre-driver stage can be configured to amplify an input signal to generate a first amplified signal. The driver stage can be configured to amplify the first amplified signal to generate a second amplified signal. The final stage can be configured to amplify the second amplified signal to generate an output amplified signal. The final stage can include a peak amplifier, a main amplifier, a peak input matching network, a peak output matching network, a main input matching network and a main output matching network. The peak output network can include a first matching section and a second matching section. The first matching section and the second matching section can perform different impedance matching. The main input matching network can include a harmonic trapping section configured to trap a second harmonic of the second amplified signal.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a diagram showing an example system that can implement three stage power amplifier with peak output match in one embodiment.

FIG. 2 is a diagram showing another example system that can implement three stage power amplifier with peak output match in one embodiment.

FIG. 3 is a diagram showing an example of a three stage power amplifier with peak output match in one embodiment.

FIG. 4 is a diagram showing an example final stage of a three stage power amplifier with peak output match in one embodiment.

FIG. 5 is a diagram showing an example implementation of the final stage of FIG. 4 in one embodiment.

FIG. 6 is a diagram showing a relationship between an absence and a presence of a peak output matching network in amplifier modules.

FIG. 7 is a diagram showing details of a balanced driver stage of a three stage power amplifier with peak output match in one embodiment.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

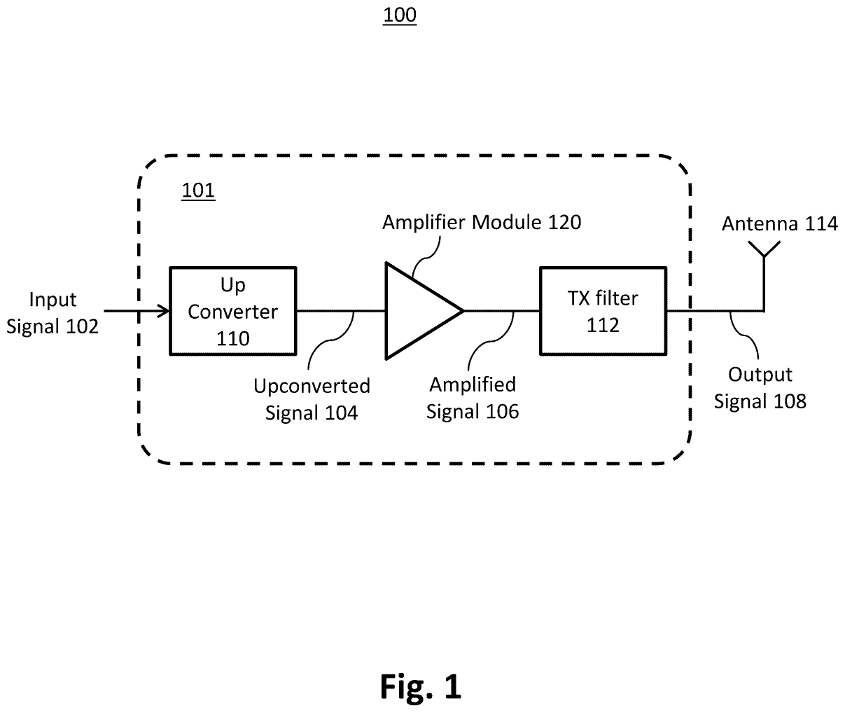

FIG. 1 is a diagram showing an example system that can implement a three stage power amplifier with peak output match in one embodiment. System 100 in FIG. 1 can be part of a radio frequency (RF) transmitter, or other types of RF transmission devices such as beamforming integrated circuits (ICs), that includes a plurality of communication channels connected to a phased array including a plurality of antenna elements. A communication channel 101 among the plurality of communication channels in system 100 and an antenna 114 among the phased array are shown in FIG. 1. Communication channel 101 can be implemented by one or more semiconductor devices.

Communication channel 101 can include at least an upconverter 110, an amplifier module 120 and a transmission (TX) filter 112. An input signal 102 encoding data representing information and/or messages can be provided to communication channel 101. Communication channel 101 can upconvert, amplify and filter input signal 102 to generate an output signal 108 encoding the same data as input signal 102. Output signal 108 can be RF signals. Output signal 108 can be provided to an antenna 114 and antenna 114 can emit radio waves representing output signal 108 to wirelessly transmit output signal 108 to a destination device through a medium, such as air.

Upconverter 110 can receive input signal 102. Upconverter 110 can be configured to convert input signal 102 into an upconverted signal 204 that has a higher frequency than input signal 202. Amplifier module 120 can receive upconverted signal 104 from upconverter 110. Amplifier module 120 can be a power amplifier configured to amplify upconverted signal 104 into an amplified signal 106. Amplifier module 120 can boost the signal strength or gain, or increase the power level, of upconverted signal 104 to a level suitable for transmission over long distances or through various mediums. The increased signal strength can also extend the coverage area of the RF transmitter including communication channel 101, allowing RF waves emitted from antenna 114 to cover relatively larger geographical areas. Amplifier module 120 can also match the impedance of communication channel 101 to the impedance of antenna 114 for maximum power transfer and optimizing the efficiency of the transmission.

TX filter 112 can receive amplified signal 106. TX filter 112 can be configured to suppress harmonics in amplified signal 106 (e.g., harmonics may be generated by amplifier module 120), filter out unwanted frequencies (e.g., frequencies different from the carrier frequency) and attenuate noise that might be present in amplified signal 106 to improve SNR. The filtered version of amplified signal 106 can be outputted by TX filter 112 as output signal 108.

In an aspect, multiple-input multiple-output (MIMO) systems can be used for implementing high frequency communication technologies, such as Wi-Fi, 4G, 5G, 6G, etc. MIMO systems use multiple antennas at both the transmitter and receiver to improve communication performance. Conventional two-stage power amplifiers in MIMO systems can include a final output stage that can be implemented by a Doherty amplifier including a peak path and a main path. An efficiency of conventional Doherty amplifiers can be maximized at a specific operating frequency range, but the efficiency can decrease at a relatively fast pace as the operating frequency increases. Due to this decrease of efficiency, conventional Doherty amplifiers may not be able to maintain satisfying efficiency at high frequency technologies.

In an aspect, a final stage of conventional Doherty power amplifier modules may not include a peak output matching network before the signals of the peak path and main path are combined, and can include an impedance transformer matching networking to perform impedance matching between the final stage and the load (e.g., antenna 114) receiving the amplified signal from the final stage. To be described in more detail below, amplifier module 120 can be implemented as a three-stage amplifier including a final stage that can provide a baseband matching topology that is integrated within the power amplifier module 120. The integrated baseband matching can provide relatively low envelope impedance and can maximum instantaneous bandwidth (IBW) operation with optimal linearity. As a result of the integrated baseband matching, the outputs from the peak and main path of the Doherty configuration in the final stage can be directly combined into a 50-ohm impedance with no extra impedance transformer after the combination. The elimination of impedance transformer after the combination can provide case of integration in massive multiple input multiple output (MIMO) systems. The integrated matching of the peak path can also improve the efficiency of the system at high frequency applications.

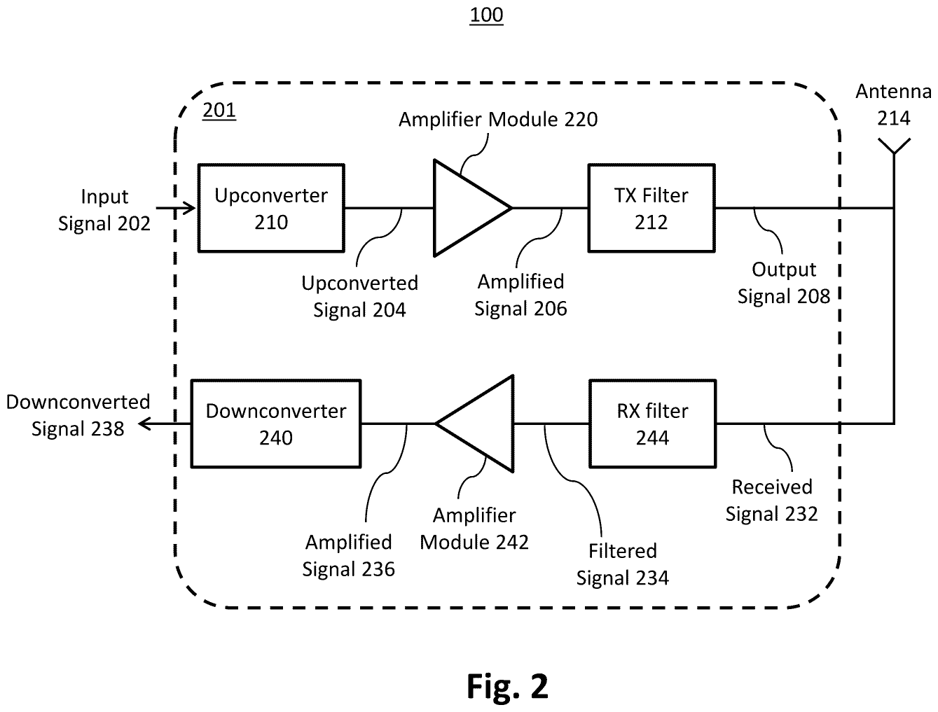

FIG. 2 is a diagram showing another example system that can implement a three stage power amplifier with peak output match in one embodiment. Descriptions of FIG. 2 can reference components shown in FIG. 1. System 200 in FIG. 2 can be part of a radio frequency (RF) transceiver, or other types of RF communication devices such as beamforming integrated circuits (ICs), that includes a plurality of communication channels connected to a phased array including a plurality of antenna elements. A communication channel 201 among the plurality of communication channels in system 200 and an antenna 218 among the phased array are shown in FIG. 2. Communication channel 201 can be implemented by one or more semiconductor devices.

Communication channel 201 can include a transmitter path and a receiver path. The transmitter path can be implemented for generating signals to be transmitted from antenna 214 and the receiver path can be implemented for processing signals received by antenna 214. The transmitter path can include at least an upconverter 210, an amplifier module 220 and a transmission (TX) filter 212. An input signal 202 encoding data representing information and/or messages can be provided to communication channel 201. Communication channel 201 can upconvert, amplify and filter input signal 202 to generate an output signal 208 encoding the same data as input signal 202. Output signal 208 can be RF signals. Output signal 208 can be provided to an antenna 214 and antenna 214 can emit radio waves representing output signal 208 to wirelessly transmit output signal 208 to a destination device through a medium, such as air.

Upconverter 210 can receive input signal 202. Upconverter 210 can be configured to convert input signal 202 into an upconverted signal 204 that has a higher frequency than input signal 202. Amplifier module 220 can receive upconverted signal 204 from upconverter 210. Amplifier module 220 can be a power amplifier configured to amplify upconverted signal 204 into an amplified signal 206. Amplifier module 220 can boost the signal strength or gain, or increase the power level, of upconverted signal 204 to a level suitable for transmission over long distances or through various mediums. The increased signal strength can also extend the coverage area of the RF transmitter including communication channel 201, allowing RF waves emitted from antenna 214 to cover relatively larger geographical areas. Amplifier module 220 can also match the impedance of communication channel 201 to the impedance of antenna 214 for maximum power transfer and optimizing the efficiency of the transmission.

TX filter 212 can receive amplified signal 206. TX filter 212 can be configured to suppress harmonics in amplified signal 206 (e.g., harmonics may be generated by amplifier module 220), filter out unwanted frequencies (e.g., frequencies different from the carrier frequency) and attenuate noise that might be present in amplified signal 206 to improve SNR. The filtered version of amplified signal 206 can be outputted by TX filter 212 as output signal 208.

The receiver path can include at least a downconverter 240, an amplifier module 242 and a receiver (RX) filter 244. Antenna 214 can receive a received signal 232 encoding data representing information and/or messages. Communication channel 201 can filter, amplify and downconvert received signal 232 to generate a downconverted signal 238 encoding the same data as received signal 232. Received signal 232 can be a RF signal.

RX filter 244 can receive received signal 232. RX filter 244 can be configured to filter out unwanted frequencies and attenuate noise that might be present in received signal 232 to generate filtered signal 234. Filtering received signal 232 to generate filtered signal 234 can also provide protection to amplifier module 242 by filtering out excessively strong out-of-band signals or signals with high levels of interference since amplifying such signals can risk damaging amplifier module 242.

Amplifier module 242 can receive filtered signal 234. Amplifier module 242 can be a low power amplifier configured to amplify signals with relatively low power levels. Using a low power amplifier in the receiver path can amplify filtered signal 234 to a level that can be processed by subsequent stages of the receiver path, such as downconverter 240, without introducing excessive noise or distortion. Also, using a low power amplifier in the receiver path can incur relatively less cost when compared to higher power amplifiers. Amplifier module 242 can amplify filtered signal 234 to generate an amplified signal 236. Downconverter 240 can receive amplified signal 236. Downconverter 240 can be configured to convert amplified signal 236 into a downconverted signal 238 that has a lower frequency than input signal 202. Downconverter 240 can send downconverted signal 238 to a controller or processor for further decoding.

Amplifier module 220 shown in FIG. 2 can be identical to amplifier module 120 shown in FIG. 1. Amplifier module 220, similar to amplifier module 120, can be implemented as a three-stage amplifier with peak output match integrated in the final stage to improve efficiency at high frequency applications. The three-stage amplifier described herein including a pre-driver stage, a driver stage and an output or final stage with peak output matching integrated in the same chip can be applicable to RF transmitters (e.g., system 100) and/or RF transceivers (e.g., system 200).

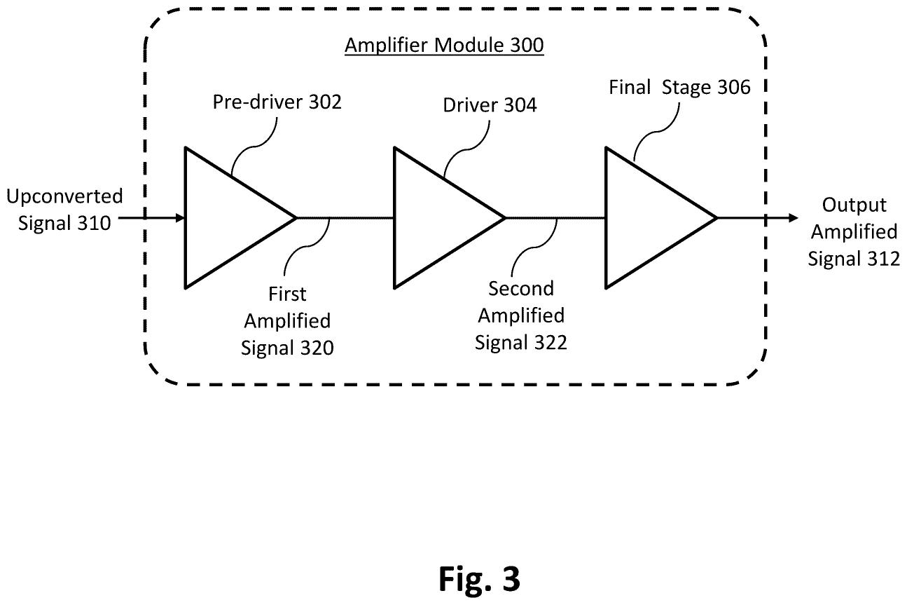

FIG. 3 is a diagram showing an example of a three stage power amplifier with peak output match in one embodiment. Descriptions of FIG. 3 can reference components shown in FIG. 1 and FIG. 2. An amplifier module 300 is shown in FIG. 3. Amplifier module 300 can be an implementation of amplifier module 120 in FIG. 1 and/or amplifier module 220 in FIG. 2. Amplifier module 300 can be a three stage amplifier including a pre-diver stage 302 (“pre-driver 302”), a driver stage 304 (“driver 304”) and a final stage 306 (can also be referred to as output stage). Amplifier module 300 can receive an upconverted signal 310 and amplify upconverted signal 310 to generate an output amplified signal 312, where output amplified signal 312 has a higher signal strength than upconverted signal 310. The difference in signal strengths between upconverted signal 310 and output amplified signal 312 can be dependent on the gain of amplifier module 300. Upconverted signal 310 can be upconverted signal 104 in FIG. 1 or upconverted signal 204 in FIG. 2, and output amplified signal 312 an be amplified signal 106 in FIG. 1 or amplified signal 206 in FIG. 2. Amplifier module 300 can be an integrated circuit (IC) implemented by semiconductor devices, and pre-diver stage 302, driver stage 304 and final stage 306 can be integrated in the same IC.

In an aspect, the signal level of a signal is the strength or intensity of the signal that can be measured in decibels (dB) or volts. The signal level of a signal can indicate how strong or weak a signal is at a particular point in a system. For example, in audio applications, the signal level of an audio signal can be referred to as the volume of a sound. On the other hand, a gain of a signal is an amount of increase in amplitude or power of the signal in response to being processed by an amplifier or other components configured to amplify signals. The gain an be a measure of how much an amplifier amplifies or boosts a signal compared to its input.

Pre-driver 302 can be configured to process upconverted signal before driver stage 304 performs amplification. In one or more embodiments, pre-driver 302 can be configured to boost the signal level of upconverted signal 210 to a signal level suitable for driver stage 304 to amplify without distortion. The boosted signal generated by pre-driver 302 can be outputted as first amplified signal 320. Pre-driver 302 can also be configured to perform signal conditioning such as equalization (e.g., adjust frequency response) and/or filtering (e.g., removing unwanted frequencies) and to reduce noise in upconverted signal 210. Pre-driver stage 302 can have a relatively less gain when compared with driver stage 304 and final stage 306. In one embodiment, pre-driver stage 302 can be implemented by a Gallium Arsenide (GaAs) device or GaAs transistor.

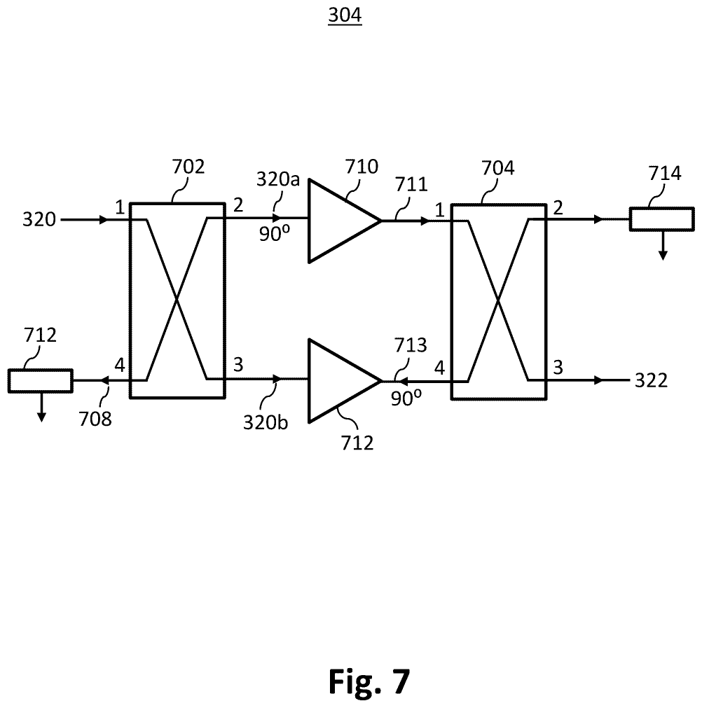

Driver stage 304 can receive first amplified signal 320. Driver stage 304 can be configured to boost the signal level of amplified signal 320 to a target level for an attached antenna (e.g., antenna 114 in FIG. 1 or antenna 214 in FIG. 2) to transmit wirelessly. The boosted signal generated by driver 304 can be outputted as second amplified signal 322. Driver stage 304 can be implemented with a balanced architecture by including a high absorption load to pre-driver stage 302 to eliminate reflection from driver stage 304 towards pre-driver stage 302, thus eliminating the need for an isolator. Details of driver stage 304 are presented in FIG. 7 below.

In one or more embodiments, a splitter can be connected between the output of driver stage 304 and the input of final stage 306. An interstage matching network can be connected between the output of driver stage 304 and the input of the splitter for performing impedance matching between driver stage 304 and final stage 306. The interstage matching network can be implemented using relatively simple components that allow driver stage 304 to directly connect to final stage 306 without using RF hot vias. The interstage matching network between driver stage 304 and final stage 306 can provide tunability and performance optimization of the overall power amplifier module 300. In one embodiment, implementation of the interstage matching network can include using copper coins to improve cooling of driver stage 304 and final stage 306.

Final stage 306 can receive second amplified signal 322. Final stage 306 can be configured to further boost second amplified signal 322 to generate output amplified signal 312. Final stage 306 can output amplified signal 312 to a load, such as antenna 114 in FIG. 1 or antenna 214 in FIG. 2. Final stage 306 can be configured to output amplified signal 312 while maintaining relatively low distortion and high fidelity. In one or more embodiments, final stage 306 can include one or more power matching networks for matching the impedance of amplifier module 300 to the impedance of the load receiving output amplified signal 312 in order to maximize power transmission efficiency. Specifically, final stage 306 can include a matching network for matching the peak path output such that the peak and main path outputs of final stage 306 can be directly combined into a 50-ohm impedance with no extra impedance transformer after the combination and the output of final stage 306.

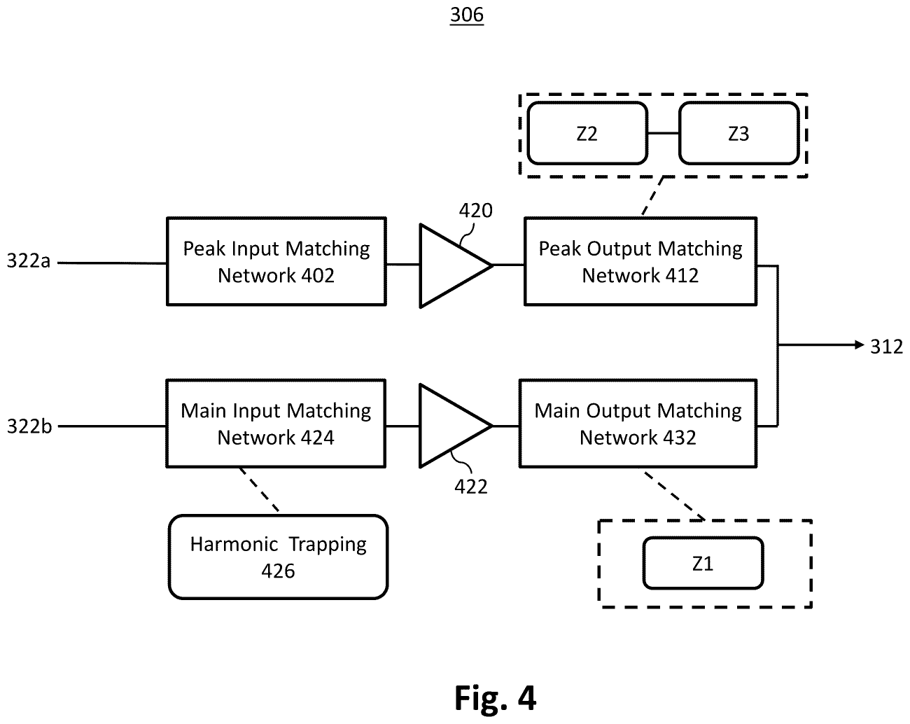

FIG. 4 is a diagram showing an example final stage of a three stage power amplifier with peak output match in one embodiment. Description of FIG. 4 can reference components shown in FIG. 1 to FIG. 3. In an example embodiment shown in FIG. 4, final stage 306 can be implemented using amplifiers 420, 422, a peak input matching network 402, a peak output matching network 412, a main input matching network 424 and a main output matching network 432. In one embodiment, the configuration of final stage 306 shown in FIG. 4 can optimize optimal back off match of the main amplifier (e.g., amplifier 422), wideband off state impedance of the peak amplifier (e.g., amplifier 420), peak power match of the main and peak amplifiers, and output second harmonic match of the main and peak amplifiers at peak power.

Final stage 306 can be implemented by a Doherty amplifier such that amplifier 420 can be a peak amplifier and amplifier 422 can be a main amplifier. In one embodiment, amplifier 420 can be a class C power amplifier and amplifier 422 can be a class AB power amplifier. In one or more embodiments, amplifiers 420, 422 can be implemented by Gallium Nitride (GaN) devices or GaN transistors, including but not limited to Gallium Nitride Metal Semiconductor Field-effect transistors (GaN MESFET), GaN high-electron-mobility transistor (HEMT), GaN heterostructure field-effect transistor (HFET), etc.

In one embodiment, amplifier 420 can have a periphery size that ranges from the periphery size of amplifier 422 (e.g., device periphery ratio of 1:1) up to a periphery size equivalent to twice the periphery size of amplifier 422 (e.g., device periphery ratio of 1:2). When the periphery size is same as the periphery size of amplifier 422, final stage 306 can have a up to a periphery size equivalent to twice the periphery size of amplifier 422. In one embodiment, a drain voltage of pre-driver stage 302 can be 5 volts (V) and drain voltages of driver stage 304 and final stage 306 can be 50V.

In one embodiment, the electrical length of the main output matching network 432 can be designed to be between 45 and 135°, with 90° at center design frequency. The main output matching network 432 can be implemented as a one section matching network with a characteristic impedance Z1 that can be optimized to maximize the overall performance of the power amplifier module 300 across wide bandwidth. The main output matching network 432 can be implemented using, for example, surface mount components, microstrip lines, or a combination of both.

In one embodiment, the electrical length of the peak output matching network 412 can be designed to be between 135 and 225°, with 180° at center design frequency. The peak output matching network 412 can include two sections of matching networks (e.g., Z2, Z3) and can be implemented using surface mount components, microstrip lines, or a combination of both. The characteristic impedances Z2 and Z3 of each section in the output peak matching network 412 can be optimized to maximize the overall performance of power amplifier module 300 across wide bandwidth.

As a result of including peak output matching network 412 between the output of the peak amplifier (e.g., amplifier 420) and the combination point of the outputs from the peak and main path of the Doherty configuration in final stage 306, the output from the peak and main paths can be directly combined into a 50-ohm impedance with no extra impedance transformer after the combination. Hence, a 50-ohm input/output with DC blocking cap and baseband matching inside the power amplifier module 300 can be realized without extra matching networks or elements required outside of the power amplifier module 300 and can provide ease of integration in massive multiple input multiple output (MIMO) systems.

The input peak matching network 412 and the input main matching network 424 can be implemented by microstrip and surface mount technology (SMT)-based matching or delay networks that can provide optimal input match of the main and peak paths for wideband gain performance. In one embodiment, input main matching network 424 can include a harmonic trapping circuit 426 to boost an efficiency of the power amplifier module 300 by trapping the second harmonics of intermediate signal 322b prior to amplifier 420 receiving intermediate signal 322b. The main and peak paths can have two separate phasing networks to minimize the impact of overmold package and process variation, such that a distributed delay compensation can be provided. Overall, the incorporation of the output peak matching network 432 and the harmonic trap performed by main input matching network 424 can improve efficiency of power amplifier module 300 by improving the linearity of the power amplifier module 300. The configuration of final stage 306 shown in FIG. 4 can optimize optimal back off match of the main amplifier (e.g., amplifier 422), wideband off state impedance of the peak amplifier (e.g., amplifier 420), peak power match of the main and peak amplifiers and output second harmonic match of the main and peak amplifiers at peak power.

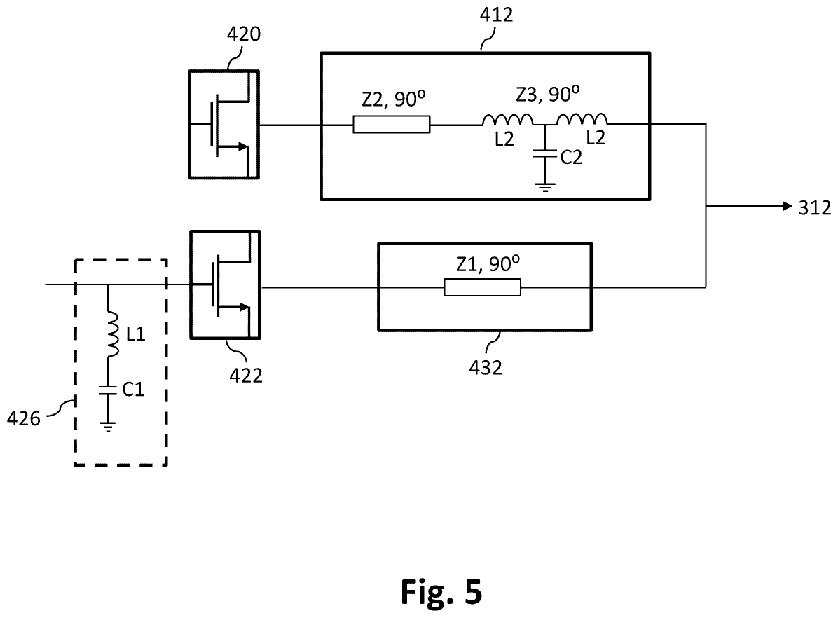

FIG. 5 is a diagram showing an example implementation of the final stage of FIG. 4 in one embodiment. Descriptions of FIG. 5 can reference components shown in FIG. 1 to FIG. 4. In an example embodiment shown in FIG. 5, amplifiers 420, 422 can be GaN devices with a peak-to-main gate periphery ratio denoted as r, where amplifier 420 is the peak amplifier of the peak path and amplifier 422 is the main amplifier of the main path in final stage 306. The peak-to-main gate periphery ratio between amplifier 420, 422 can be the relative periphery lengths of the peak amplifier's gate compared to the main amplifier's gate. A higher peak-to-main gate periphery ratio indicates that a larger portion of the output power is being contributed by the peak amplifier, which may increase an overall efficiency of final stage 306. In one embodiment, the peak-to-main gate periphery ratio can be within a range of 1:1 to 1:2.

In the example embodiment shown in FIG. 5, the harmonic trapping circuit 426 can be implemented by a resonant circuit, such as a LC circuit, in a shunt arrangement. The LC circuit implementing the harmonic trapping circuit 426 can include an inductor with inductance L1 and a capacitor with capacitance C1 connected in series and between the gate of amplifier 422 and ground. The values of L1 and C1 can be chosen for trapping second harmonics of intermediate signal 322b prior to amplifier 420 receiving intermediate signal 322b. The trapping of second harmonics performed by harmonic trapping circuit 426 can increase an efficiency of the final stage 306 since second harmonics of intermediate signal 322b are being shunt to ground before amplifier 420 receives intermediate signal 322b.

In the example embodiment shown in FIG. 5, the main output matching network 432 can be implemented by a microstrip line that provides an impedance Z1 and a phase shift of 90 degrees. A length of the microstrip line in main output matching network 432 can be chosen such that it provides the impedance Z1 and 90-degree phase shift on the signal being outputted from amplifier 422. In one embodiment, the impedance Z1 can dependent on r and an optimal impedance of amplifier 422 denoted as R_{opt,M}, and Z1 can be expressed as:

$$Z 1 = \sqrt{50 \cdot ( r + 1 ) \cdot {R}_{opt , M}}$$

In the example embodiment shown in FIG. 5, a first section of the peak output matching network 412 can be implemented by a microstrip line that provides an impedance Z2 and a phase shift of 90 degrees. A second section of the peak output matching network 412 can be implemented by a combination of lump elements, which can be surface mount elements including one or more of resistors, inductors and capacitors, that provides an impedance Z3 and a phase shift of 90 degrees. A length of the microstrip line in the first section of peak output matching network 412 can be chosen such that it provides the impedance Z2 and 90-degree phase shift on the signal being outputted from amplifier 420. An arrangement of lump elements, and attributes of the lump elements, in the second section of peak output matching network 412 can be chosen such that it provides the impedance Z3 and 90-degree phase shift on the signal that underwent the Z2 impedance and 90-degree phase shift. The two consecutive 90-degree phase shifts provided by the first and second sections of peak output matching network 412 can provide an overall phase shift of 180 degrees on the signal being outputted by amplifier 420. In the embodiment shown in FIG. 5, the lump elements implementing the second section of peak output matching network 412 can be a LCL circuit or filter with two inductors having inductance L2 connected in series and a capacitor having capacitances C2 connected between the two inductors and ground. In one embodiment, the impedance Z2, Z3 can be dependent on r and an optimal impedance of amplifier 420 denoted as R_{opt,P}, and a relationship between Z2 and Z3 can be expressed as:

$$Z 2 = Z 3 \times \sqrt{( {R}_{opt , P} / 50 \cdot ( 1 + \frac{1}{r} ) )}$$

As shown in the example embodiment of FIG. 5, different combinations of lump elements and microstrips can be used for achieving the desired impedance and phase shifts in peak output matching network 412 and main output matching network 432. The selection of lump elements, microstrip lines, arrangements of the selected lumped elements, attributes (e.g., inductance, resistance, capacitance) of the lump elements, can be arbitrary as long as the desired impedances Z1, Z2, Z3 and desired phase shifts are achieved.

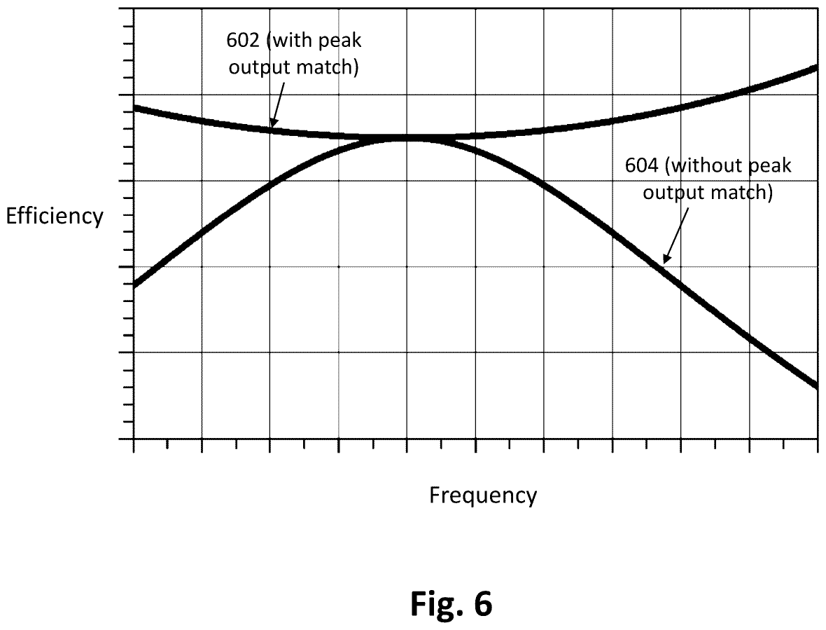

FIG. 6 is a diagram showing a relationship between an absence and a presence of a peak output matching network in amplifier modules. Description of FIG. 6 can reference components shown in FIG. 1 to FIG. 5. In an example shown in FIG. 6, a curve 602 represents a change in efficiency with changes in operating frequency of amplifier module 300 implemented with peak output matching network 412. A curve 604 represents a change in efficiency with changes in operating frequency of an amplifier module implemented without peak output matching network 412.

As shown in FIG. 6, the efficiency of the amplifier module implemented without peak output matching network 412 decreases as operating frequency decreases and increases. Therefore, amplifier modules without peak output matching network 412 may not be suitable for high frequency applications. Further, without peak output matching network 412, additional matching networks after the output of the amplifier module may be needed to compensate for the decreased efficiency in high frequency applications.

However, as shown by curve 602, the efficiency of the amplifier module 300 implemented with peak output matching network 412 increases as operating frequency decreases and increases. Therefore, amplifier module 300 with peak output matching network 412 may be suitable for high frequency applications, and additional matching networks after the output of amplifier module 300 are not needed.

FIG. 7 is a diagram showing details of a balanced driver stage of a three stage power amplifier with peak output match in one embodiment. Description of FIG. 6 can reference components shown in FIG. 1 to FIG. 6. In an example embodiment shown in FIG. 7, driver stage 304 can include a hybrid coupler 702, a hybrid coupler 704, an amplifier 710 and an amplifier 712. In one embodiment, amplifiers 710, 712 can be class AB amplifiers. In one or more embodiments, amplifiers 710, 712 can be implemented by Gallium Nitride (GaN) devices or GaN transistors, including but not limited to Gallium Nitride Metal Semiconductor Field-effect transistors (GaN MESFET), GaN high-electron-mobility transistor (HEMT), GaN heterostructure field-effect transistor (HFET), etc. Driver stage 304 can be implemented by a balanced amplifier architecture with hybrid coupler 702 configured as a power splitter and hybrid coupler 704 configured as a combiner.

Hybrid coupler 702 can receive first amplified signal 320 from pre-driver stage 302. Hybrid coupler 702 can be configured to generate intermediate signals 320a, 320b using first amplified signal 320. In one embodiment, hybrid coupler 702 can be a 90-degree hybrid coupler, or a quadrature coupler, configured as a power splitter to perform a 3-dB (e.g., equal) power split, such as dividing an input signal (e.g., first amplified signal 320) evenly between two output ports with 3 dB coupling.

First amplified signal 320 can be received by Port 1 (“1”) of hybrid coupler 702. Port 1 and Port 4 (“4”) of hybrid coupler 702 are at a 180-degree in-phase relationship. In an aspect, when a signal is applied to Port 1 and Port 4 of hybrid coupler 702 is terminated with a load 502, as shown in FIG. 7, the termination can cause power to be equally split between Port 2 (“2”) and Port 3 (“3”) of hybrid coupler 702. Therefore, first amplified signal 320 being received at Port 1 of hybrid coupler 702 is divided between the two output ports, Port 2 and Port 3 with half the power flowing to Port 2 (e.g., amplified signal 320a) and the other half flowing to Port 3 (e.g., intermediate signal 320b). Any reflection from mismatches at the output ports of hybrid coupler 702, such as Port 2 and Port 3, can flow to Port 4. Port 4 of hybrid coupler 702 can be configured as an isolation port that terminates standing waves and reflections into load 712. In one embodiment, load 712 can be a 50-ohm load resistor.

The output signals from hybrid coupler 702, such as intermediate signals 320a, 320b, can have a phase difference of 90 degrees. Intermediate signal 320a can be a 90-degree shift version of first amplified signal 320, and intermediate signal 320b can be identical to, and/or in-phase with, first amplified signal 320. Hybrid coupler 702 can further include a high absorption load 712 that isolates one of the ports of hybrid coupler 702 such that reflections from driver stage 304 towards pre-driver stage 302 can be absorbed by the high absorption load 712.

Amplifier 710 can be configured to amplify intermediate signal 320a to generate an amplified intermediate signal 711. Amplifier 712 can be configured to amplify intermediate signal 320b to generate an amplified intermediate signal 713. Hybrid coupler 704 can be a 90-degree hybrid coupler, or a quadrature coupler, configured as a combiner to combine amplified intermediate signals 711, 713 to generate second amplified signal 322. In one embodiment, amplifiers 710, 712 can be identical such that amplifiers 710, 712 can perform the same level of amplification, such as increasing the amplitudes of intermediate signals 320a, 320b by the same amount.

Intermediate signal 320a amplified by amplifier 710 can be received by Port 1 (“1”) of hybrid coupler 704. Intermediate signal 320b amplified by amplifier 712 can be received by Port 4 (“4”) of hybrid coupler 704. The phases of intermediate signals 320a, 320b are 90 degrees out-of-phase with each other. In an aspect, Port 3 (“3”) is 90 degrees out-of-phase with Port 1, and this phase mismatch can cause the powers to add to the output port, Port 3, and the mismatch can be absorbed by a load 714 connected to an isolated Port 2 (“2”). Therefore, hybrid coupler 704 is configured as a combiner that combines intermediate signals 320a, 320b amplified by amplifiers 710, 712 to generate second amplified signal 322.

In an aspect, conventional systems can implement amplifier module 120 using a two-stage power amplifier that includes a driver stage for boosting signal amplitude and an output or final stage for optimizing efficiency. An amount of gain boost from a two-stage power amplifier can be defined and limited depending on the device types and sizes in the driver stage and final stage. In an aspect, to increase the amount of the gain boost by the two-stage power amplifier, a pre-driver can be connected to the input of the two-stage power amplifier to provide a relatively small boost to the signal before the signal be inputted to the driver stage of the power amplifier. In these conventional systems, the pre-driver can be a separate chip external to the two-stage power amplifier chip. However, the added pre-driver can sometimes create reflections towards the pre-driver from the driver stage of the power amplifier, causing mismatch and creation of standing waves. As a result of these reflections, not the entire signal may pass through into the power amplifier and the overall performance can be degraded. Some conventional systems address the reflections by adding an isolator or circulator between the pre-driver and the power amplifier, but the added isolator increases costs and real estate of the circuit board.

The capability of the balanced driver topology of driver stage 304 to absorb reflections can allow a pre-driver (e.g., pre-driver stage 302) to be integrated and absorbed into a single power amplifier module without a need for isolation components. The isolation internal to driver stage 304 can enhances the power and temperature stability of the active devices using the three-stage power amplifier shown herein. The three-stage power amplifier shown herein can also enable higher gain for applications that require the higher gain. Also, the three-stage power amplifier shown herein can leverages GaN technology in both driver and final stages, thus enables improved overall RF performance (e.g., bandwidth, efficiency, output power). GaN devices in the driver and final stages can provide higher cut-off frequency, reduce device parasitic, and provide higher power density when compared to conventional devices such as Silicon-based lateral double-diffused metal-oxidesemiconductor (Si LDMOS).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. An integrated circuit comprising:
a pre-driver stage configured to amplify an input signal to generate a first amplified signal;
a driver stage configured to amplify the first amplified signal to generate a second amplified signal; and
a final stage configured to amplify the second amplified signal to generate an output amplified signal, wherein the final stage comprises:
a peak amplifier;
a main amplifier;
a peak input matching network;
a peak output matching network comprising a first matching section and a second matching section, wherein the first matching section and the second matching section perform different impedance matching;
a main input matching network comprising a harmonic trapping section configured to trap a second harmonic of the second amplified signal; and
a main output matching network.

2. The integrated circuit of claim 1, wherein the final stage is implemented by a Doherty amplifier comprising a first GaN device configured as the peak amplifier and a second GaN device configured as the main amplifier.

3. The integrated circuit of claim 1, wherein the first matching section and the second matching section of the peak output matching network are implemented by at least one of microstrip lines and lump elements.

4. The integrated circuit of claim 1, wherein the harmonic trapping section of the main input matching network is implemented by a LC circuit in a shunt arrangement.

5. The integrated circuit of claim 1, wherein the pre-driver stage is implemented by a Gallium Arsenide (GaAs) device.

6. The integrated circuit of claim 1, wherein the driver stage comprises:
a first hybrid coupler configured to:
split the first amplified signal into a first intermediate signal and a second intermediate signal;
absorb reflections resulted from mismatches between the first intermediate signal and the second intermediate signal;
a first amplifier configured to amplify the first intermediate signal to generate a first amplified intermediate signal;
a second amplifier configured to amplify the second intermediate signal to generate a second amplified intermediate signal;
a second hybrid coupler configured to:
absorb reflections resulted from mismatches between the first amplified intermediate signal and the second amplified intermediate signal; and
combine the first amplified intermediate signal and the second intermediate amplified signal to generate the second amplified signal.

7. The integrated circuit of claim 6, wherein the first hybrid coupler and the second hybrid coupler are quadrature couplers.

8. A system comprising:
a plurality of antennas;
a plurality of transmission channels, wherein a transmission channel comprises an amplifier module comprising:
a pre-driver stage configured to amplify an input signal to generate a first amplified signal;
a driver stage configured to amplify the first amplified signal to generate a second amplified signal; and
a final stage configured to amplify the second amplified signal to generate an output amplified signal, wherein the final stage comprises:
a peak amplifier;
a main amplifier;
a peak input matching network;
a peak output matching network comprising a first matching section and a second matching section, wherein the first matching section and the second matching section perform different impedance matching;
a main input matching network comprising a harmonic trapping section configured to trap a second harmonic of the second amplified signal; and
a main output matching network.

9. The system of claim 8, wherein the final stage is implemented by a Doherty amplifier comprising a first GaN device configured as the peak amplifier and a second GaN device configured as the main amplifier.

10. The system of claim 9, wherein the first matching section and the second matching section of the peak output matching network are implemented by at least one of microstrip lines and lump elements.

11. The system of claim 9, wherein the harmonic trapping section of the main input matching network is implemented by a LC circuit in a shunt arrangement.

12. The system of claim 8, wherein the pre-driver stage is implemented by a Gallium Arsenide (GaAs) device.

13. The system of claim 8, wherein the driver stage comprises:
a first hybrid coupler configured to:
split the first amplified signal into a first intermediate signal and a second intermediate signal;
absorb reflections resulted from mismatches between the first intermediate signal and the second intermediate signal;
a first amplifier configured to amplify the first intermediate signal to generate a first amplified intermediate signal;
a second amplifier configured to amplify the second intermediate signal to generate a second amplified intermediate signal;
a second hybrid coupler configured to:
absorb reflections resulted from mismatches between the first amplified intermediate signal and the second amplified intermediate signal; and
combine the first amplified intermediate signal and the second intermediate amplified signal to generate the second amplified signal.

14. The system of claim 13, wherein the first hybrid coupler and the second hybrid coupler are quadrature couplers.

15. A system comprising:
a plurality of antennas;
a plurality of receiver channels configured to process signals being received by the plurality of antennas;
a plurality of transmission channels, wherein a transmission channel comprises an amplifier module comprising:
a pre-driver stage configured to amplify an input signal to generate a first amplified signal;
a driver stage configured to amplify the first amplified signal to generate a second amplified signal; and
a final stage configured to amplify the second amplified signal to generate an output amplified signal, wherein the final stage comprises:
a peak amplifier;
a main amplifier;
a peak input matching network;
a peak output matching network comprising a first matching section and a second matching section, wherein the first matching section and the second matching section perform different impedance matching;
a main input matching network comprising a harmonic trapping section configured to trap a second harmonic of the second amplified signal; and
a main output matching network.

16. The system of claim 15, wherein the final stage is implemented by a Doherty amplifier comprising a first GaN device configured as the peak amplifier and a second GaN device configured as the main amplifier.

17. The system of claim 16, wherein the first matching section and the second matching section of the peak output matching network are implemented by at least one of microstrip lines and lump elements.

18. The system of claim 16, wherein the harmonic trapping section of the main input matching network is implemented by a LC circuit in a shunt arrangement.

19. The system of claim 15, wherein the driver stage comprises:
a first hybrid coupler configured to:
split the first amplified signal into a first intermediate signal and a second intermediate signal;
absorb reflections resulted from mismatches between the first intermediate signal and the second intermediate signal;
a first amplifier configured to amplify the first intermediate signal to generate a first amplified intermediate signal;
a second amplifier configured to amplify the second intermediate signal to generate a second amplified intermediate signal;
a second hybrid coupler configured to:
absorb reflections resulted from mismatches between the first amplified intermediate signal and the second amplified intermediate signal; and
combine the first amplified intermediate signal and the second intermediate amplified signal to generate the second amplified signal.

20. The system of claim 19, wherein the first hybrid coupler and the second hybrid coupler are quadrature couplers.
